(19) United States
(12) Patent Application Publication
(10) Pub. No.: US 2004/0113216 A1
(43) Pub. Date: Jun. 17, 2004

(54) Semiconductor diode capable of detecting hydrogen at high temperatures

(75) Inventors: Wen-Chau Liu, Tainan City (TW); Huey-Ing Chen, Tainan City (TW); Kun-Wei Lin, Tou-Liu City (TW)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: NATIONAL CHENG KUNG UNIVERSITY

(21) Appl. No.: 10/725,801

(22) Filed: Dec. 2, 2003

(30) Foreign Application Priority Data
Dec. 6, 2002 (TW) 091135484

(51) Int. Cl. H01L 27/14; H01L 29/82; H01L 29/84

(52) U.S. Cl. 257/414

(57) ABSTRACT

A semiconductor diode with hydrogen detection capability includes a semiconductor substrate, a doped semiconductor active layer formed on the substrate and made from a compound having the formula XYZ, in which X is a Group III element, Y is another Group III element different from X, and Z is a Group V element, an ohmic contact layer formed on the active layer, and a Schottky barrier contact layer formed on the active layer so as to provide a Schottky barrier therebetween. The Schottky barrier contact layer is made from a metal that is capable of dissociating a hydrogen molecule into hydrogen atoms.

### CROSS-REFERENCE TO RELATED APPLICATION

This application claims priority of Taiwanese application No. 091135484, filed on Dec. 6, 2002.

### BACKGROUND OF THE INVENTION

1. Field of the Invention

This invention relates to a semiconductor diode, more particularly to a semiconductor diode that is capable of detecting hydrogen at high temperatures.

2. Description of the Related Art

Conventional semiconductor devices for hydrogen sensors can be classified into metal-semiconductor Schottky barrier diodes, metal-oxide-semiconductor Schottky barrier diodes, metal-oxide-semiconductor capacitors, and metal-oxide-semiconductor field-effect transistors (MOSFET). Since the threshold voltage and the terminal capacitance of a MOSFET are changed upon exposure to hydrogen, the MOSFET can be used for detecting the presence of hydrogen. Hydrogen sensors made from MOSFET are expensive and have low sensitivity in detecting the presence of hydrogen, whereas hydrogen sensors made from diodes are inexpensive and the extent of change in the current-voltage relationship for the diodes upon detecting the presence of hydrogen is in the order of magnitude, which results in a higher sensitivity for the diodes as compared to the Metal-oxide-semiconductor field-effect transistors.

Hydrogen sensors made from silicon semiconductors, such as Pd/SiO₂/Si (MOS), exhibit good sensitivity in detecting the presence of hydrogen, but have a long response time. The response time is defined as the time required for electric current to reach to a value (I_{R}) represented by:

I_{R}=I_{f} (1−e⁻¹)

wherein I_{f} represents the measured final current value.

U.S. Pat. No. 6,160,278 discloses a hydrogen sensor made from a semiconductor Schottky barrier diode that includes a semi-insulating GaAs substrate, a GaAs buffer layer formed on the substrate, a doped n-GaAs active layer formed on the buffer layer, an ohmic metal contact layer formed on the active layer and serving as a first electrode, and a Schottky barrier contact layer formed on the active layer and serving as a second electrode. U.S. Pat. No. 6,293,137 discloses another semiconductor Schottky barrier diode that includes a semi-insulating InP substrate, a doped n-InP active layer formed on the substrate, an ohmic contact layer formed on the active layer and serving as a first electrode, and a Schottky barrier contact layer formed on the active layer and serving as a second electrode.

The aforesaid semiconductor diodes applicable to hydrogen sensors exhibit good sensitivity in detecting hydrogen, but are disadvantageous in that they are not suitable for detecting hydrogen in a high temperature condition and can only be used within a narrow temperature range.

The entire disclosures of U.S. Pat. No. 6,160,278 and U.S. Pat. No. 6,293,137 are incorporated herein by reference.

### SUMMARY OF THE INVENTION

Therefore, the object of the present invention is to provide a semiconductor diode for hydrogen detection that is capable of overcoming the aforesaid drawbacks of the prior art.

According to the present invention, there is provided a semiconductor diode with hydrogen detection capability that includes: a semiconductor substrate; a doped semiconductor active layer formed on the substrate and made from a compound having the formula XYZ, in which X is a Group III element, Y is another Group III element different from X, and Z is a Group V element; an ohmic contact layer formed on the active layer; and a Schottky barrier contact layer formed on the active layer so as to provide a Schottky barrier therebetween. The Schottky barrier contact layer is made from a metal that is capable of dissociating a hydrogen molecule into hydrogen atoms.

### BRIEF DESCRIPTION OF THE DRAWINGS

In drawings which illustrate an embodiment of the invention,

FIG. 1 is a schematic perspective view of a preferred embodiment of a semiconductor diode according to the present invention;

FIG. 2 is an energy band diagram showing the energy band of the preferred embodiment of this invention upon detecting the presence of hydrogen;

FIG. 3 is an I-V characteristics diagram showing I-V Curves of the preferred embodiment during detection of hydrogen under different detecting temperatures and hydrogen concentrations;

FIG. 4 is a sensitivity-vs-temperature diagram showing the sensitivity of the preferred embodiment during detection of hydrogen under different hydrogen concentrations and detecting temperatures; and

FIG. 5 is a Schottky barrier difference-vs-temperature diagram showing variation of the Schottky barrier of the preferred embodiment during detection of hydrogen under different hydrogen concentrations and detecting temperatures.

### DETAILED DESCRIPTION OF THE PREFERRED EMBODIMENT

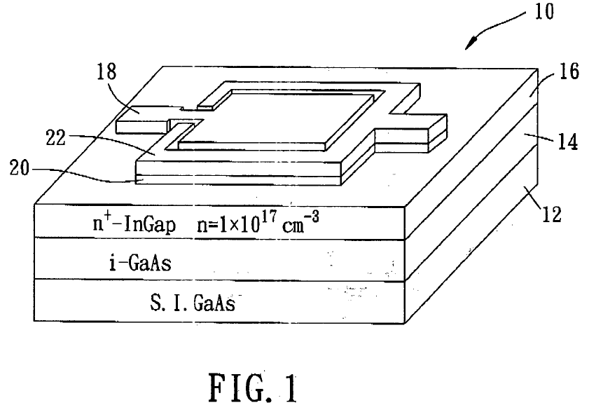

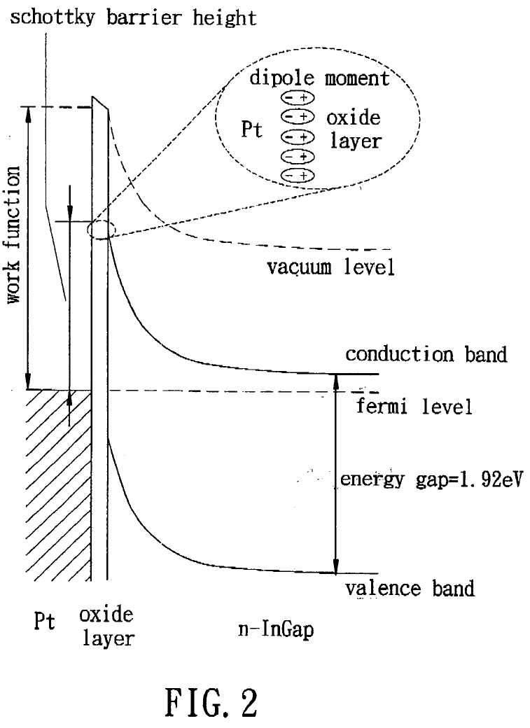

FIG. 1 illustrates the preferred embodiment of a semiconductor diode 10 suitable for use in a hydrogen sensor according to the present invention. The semiconductor diode 10 includes: a semiconductor substrate 12; a doped semiconductor active layer 16 formed on the substrate 12 and made from a compound having the formula XYZ, in which X is a Group III element, Y is another Group III element different from X, and Z is a Group V element; an ohmic contact layer 18 formed on the active layer 16 and serving as a first electrode of the semiconductor diode 10; and a Schottky barrier contact layer 22 formed on the active layer 16 so as to provide a Schottky barrier therebetween and serving as a second electrode of the semiconductor diode 10. The Schottky barrier contact layer 22 is made from a metal that is capable of dissociating a hydrogen molecule into hydrogen atoms. The hydrogen atoms thus formed diffuse through the Schottky barrier contact layer 22, and are trapped in the junction between the Schottky barrier contact layer 22 and the oxide layer 18, which results in the formation of a dipole moment layer (see FIG. 2) therebetween, which, in turn, results in an unbalance in the charge distribution therebetween. The aforesaid charge distribution reaches a new equilibrium state when the hydrogen atoms cease to diffuse through the Schottky barrier contact layer 22. The dipole moment layer reduces the width of the depletion region of the active layer 16 and the Schottky barrier of the Schottky barrier contact layer 22.

Preferably, a semiconductor buffer layer 14 is sandwiched between the substrate 12 and the active layer 16, and an oxide layer 20 is sandwiched between the active layer 16 and the Schottky barrier contact layer 22. The oxide layer 20 serves to broaden the variation range of the Schottky barrier, which results in an increase in the sensitivity of the semiconductor diode 10.

Preferably, the compound of the active layer 22 is selected from the group consisting of n-type InGaP and AlₓGa₁₋ₓAs with x=0−1. The active layer 22 preferably has a dopant concentration ranging from 1×10¹⁶ to 5×10¹⁷ atoms/cm³, and a thickness ranging from 1000 to 50000 Å.

The substrate 12 is preferably made from semi-insulating GaAs. The buffer layer 14 is preferably made from undoped i-GaAs, and has a thickness ranging from 1000 to 50000 Å. The oxide layer 20 preferably has a thickness ranging from 20 to 500 Å.

Preferably, the ohmic contact layer 18 is made from AuGe/Ni or Au/Ge, and has a thickness ranging from 1000 to 50000 Å.

Preferably, the metal of the Schottky barrier contact layer 22 is selected from the group consisting of Pt, Pd, Ni, Rh, Ru, and Ir. The Schottky barrier contact layer 22 preferably has a thickness ranging from 1000 to 20000 Å.

The present invention will now be described in greater detail in connection with the following Example.

### EXAMPLE 1

In this Example, the semiconductor diode 10 of this invention is prepared by the following steps:

forming the substrate 12 of semi-insulating GaAs;

forming the buffer layer 14 of undoped GaAs with a thickness ranging from 1000 to 50000 Å on the substrate 12 by metal organic chemical vapor deposition (MOCVD) techniques or molecular beam epitaxy (MBE) techniques;

forming the active layer 16 of doped n-type InGaP with a thickness ranging from 1000 to 50000 Å on the buffer layer 14 by MOCVD techniques or MBE techniques, the active layer 16 having a dopant concentration ranging from 1×10¹⁶ to 5×10¹⁷ atoms/cm³;

forming the ohmic contact layer 18 of AuGe/Ni alloy on the active layer 16 by wet etching, photo etching, or vacuum deposition techniques, and subsequently subjecting the assembly to an annealing process under 400° C. for about one minute;

forming the oxide layer 20 with a thickness ranging from 20 to 500 Å on the active layer 16; and

forming the Schottky barrier contact layer of Pt with a thickness ranging from 1000 to 2000 Å on the oxide layer 20 and an area of 8.5×100⁻⁴ cm².

FIGS. 2 to 5 show test results of the semiconductor diode 10 according to Example 1.

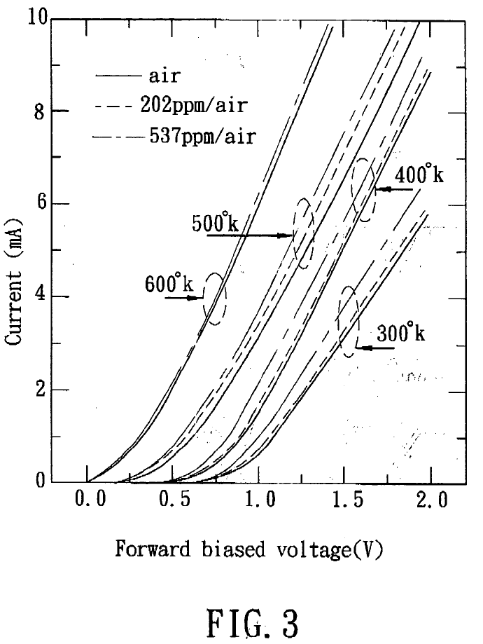

FIG. 3 shows I-V curves obtained during hydrogen detection under different hydrogen concentrations (i.e., air, i.e., zero ppm, 202 ppm, and 537 ppm) and detecting temperatures (i.e., 300K, 460K, 500K, and 600K). The results indicate that the semiconductor diode 10 of this invention is capable of detecting the presence of hydrogen at high temperatures, and that the higher the hydrogen concentration, the lower will be the Schottky barrier and the higher will be the resultant electric current. The current difference for different hydrogen concentrations at a given forward biased voltage is more prominent for lower detecting temperatures.

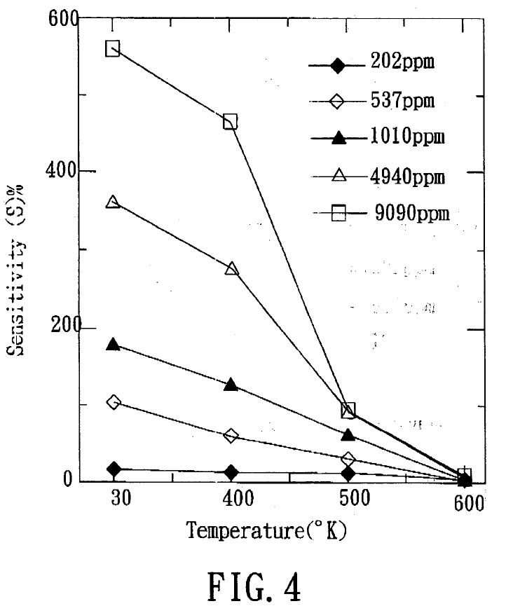

FIG. 4 shows measured sensitivity of the semiconductor diode 10 in detecting the presence of hydrogen under different hydrogen concentrations (i.e., 202 ppm, 537 ppm, 1010 ppm, 4940 ppm, and 9090 ppm) and detecting temperatures (i.e., 300K, 400K, 500K, and 600K). The sensitivity (S) is defined as S (%)=(Iₕ−Iₐ)/Iₐ (%), in which Iₕ is the measured current in the presence of hydrogen in the air, and Iₐ is the measure current without the presence of hydrogen in the air. The sensitivity of the semiconductor diode 10 is about 17% for 202 ppm hydrogen concentration at a temperature of 300K, and is about 561% for 9090 ppm hydrogen concentration at the same temperature. The higher the temperature, the lower will be the sensitivity for all the hydrogen concentrations.

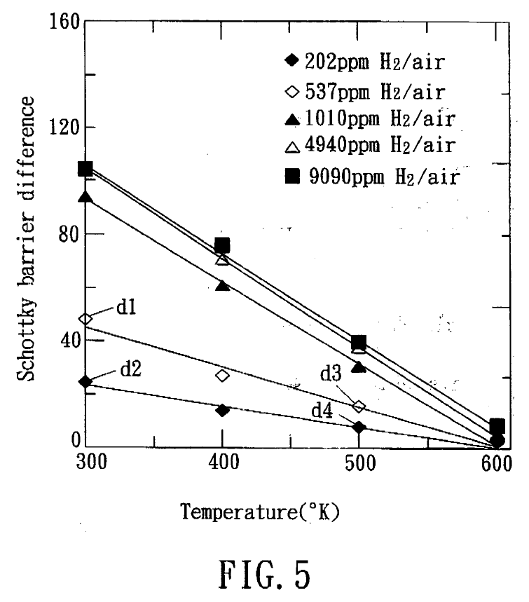

FIG. 5 shows measured variation in the Schottky barrier difference of the Schottky barrier contact layer 22 in detecting the presence of hydrogen under different hydrogen concentrations (i.e., 202 ppm, 537 ppm, 1010 ppm, 4940 ppm, and 9090 ppm) and detecting temperatures (i.e., 300K, 400K, 500K, and 600K). The aforesaid Schottky barrier difference is defined as the difference between the Schottky barrier measured without the presence of hydrogen (i.e., under air) and the Schottky barrier measured in the presence of hydrogen. The higher the temperature, the smaller will be the variation in the. Schottky barrier difference for different hydrogen concentrations. For instance, the Schottky barrier difference variation between the data point d₁ and d₂ (see FIG. 5) at a temperature of 300K is larger than that between the data point d₃ and d₄ at a temperature of 500K. Moreover, the higher the hydrogen concentration, the smaller will be the variation in the Schottky barrier difference for different temperatures. For instance, the Schottky barrier difference between the data point d₁ and d₃ (see FIG. 5) at a hydrogen concentration of 537 ppm is larger than that between the data point d₂ and d₄ at a hydrogen concentration of 202 ppm.

The response time, which is defined in the Background Of The Invention, of the semiconductor diode 10 upon application of a forward biased voltage of 0.6V thereto at a temperatures of 400K under different hydrogen concentrations (i.e., 1010 ppm, 4940 ppm, and 9090 ppm) in a test chamber (not shown) was conducted. The test chamber is connected to a hydrogen gas supply. The results show that the current rises steeply immediately after the hydrogen gas supply is turned on and drops sharply immediately after the hydrogen gas supply is turned off. The hydrogen atoms trapped in the semiconductor diode 10 diffuse backward into the test chamber after the hydrogen gas supply is turned off, thereby resulting in recovery of electric current. The hydrogen-detecting semiconductor diode 10 has a response time of 10.4 seconds for 1010 ppm hydrogen concentration, 8.3 seconds for 4940 ppm hydrogen concentration, and 3.7 seconds for 9090 ppm hydrogen concentration.

The response time of the semiconductor diode 10 upon application of a forward biased voltage of 0.6V thereto at a hydrogen concentration of 9090 ppm under different detecting temperatures (T) (i.e, 350K, 400K, 450K, 500K, and 550K) was conducted. The measured response time of the semiconductor diode 10 is 30.6 seconds when T=350K, 14.2 seconds when T=400K, 4.1 seconds when T=450K, 2.2 seconds when T=500K, and 0.9 second when T=550K. The higher the temperature, the shorter will be the response time due to the increase in hydrogen molecule collision at higher temperatures.

By using the doped InGaP as the material for the active layer 16 of the semiconductor diode 10 of this invention, the working temperature can be raised considerably and the working temperature range can be significantly broadened without sacrificing the response time and/or significantly reducing the sensitivity of the semiconductor diode 10 as compared to the aforesaid conventional semiconductor diodes applicable to hydrogen sensors.

With the invention thus explained, it is apparent that various modifications and variations can be made without departing from the spirit of the present invention.

We claim:

1. A semiconductor diode with hydrogen detection capability, comprising;
a semiconductor substrate;
a doped semiconductor active layer formed on said substrate and made from a compound having the formula XYZ, in which X is a Group III element, Y is another Group III element different from X, and Z is a Group V element;
an ohmic contact layer formed on said active layer; and
a Schottky barrier contact layer formed on said active layer so as to provide a Schottky barrier therebetween, said Schottky barrier contact layer being made from a metal that is capable of dissociating a hydrogen molecule into hydrogen atoms.

2. The semiconductor diode of claim 1, further comprising an oxide layer sandwiched between said active layer and said Schottky barrier contact layer.

3. The semiconductor diode of claim 2, wherein said oxide layer has a thickness ranging from 20 to 500 Å.

4. The semiconductor diode of claim 1, wherein said compound of said active layer is selected from the group consisting of n-type InGaP and AlₓGa₁₋ₓAs.

5. The semiconductor diode of claim 1, wherein said compound of said active layer is n-type InGaP with a dopant concentration ranging from 1×10¹⁶ to 5×10¹⁷ atoms/cm³, said active layer having a thickness ranging from 100 C to 50000 Å.

6. The semiconductor diode of claim 1, wherein said compound of said active layer is AlₓGa₁₋ₓAs with x=0-1 and a dopant concentration ranging from 1×10¹⁶ to 5×10¹⁷ atoms/cm³, said active layer having a thickness ranging from 100 C to 50000 Å.

7. The semiconductor diode of claim 1, further comprising a semiconductor buffer layer sandwiched between said substrate and said active layer.

8. The semiconductor diode of claim 7, wherein said buffer layer is made from undoped GaAs and has a thickness ranging from 1000 to 50000 Å.

9. The semiconductor diode of claim 1, wherein said substrate is made from semi-insulating GaAs.

10. The semiconductor diode of claim 1, wherein said ohmic contact layer is made from AuGe/Ni and has a thickness ranging from 1000 to 50000 Å.

11. The semiconductor diode of claim 1, wherein said ohmic contact layer is made from AuGe and has a thickness ranging from 1000 to 50000 Å.

12. The semiconductor diode of claim 1, wherein said metal of said Schottky barrier contact layer is selected from the group consisting of Pt, Pd, Ni, Rh, Ru, and Ir.

13. The semiconductor diode of claim 1, wherein said Schottky barrier contact layer has a thickness ranging from 1000 to 20000 Å.
